(19) United States
(12) Patent Application Publication
(10) Pub. No.: US 2021/0292227 A1
(43) Pub. Date: Sep. 23, 2021

(54) COLORED GLASS AND PREPARATION METHOD THEREOF

(71) Applicant: Shandong University, Weihai City (CN)

(72) Inventors: Hui Sun, Weihai City (CN); Jianhong Gong, Weihai City (CN); Tuofu Zhama, Weihai City (CN); Shumei Song, Weihai City (CN); Ruisong You, Weihai City (CN)

(73) Assignee: Shandong University, Weihai City (CN)

(21) Appl. No.: 17/150,075

(22) Filed: Jan. 15, 2021

(30) Foreign Application Priority Data
Mar. 20, 2020 (CN) 202010200630.9

(51) Int. Cl. C03C 17/36; C23C 14/35; C23C 14/00; C23C 14/06; C23C 14/08; C23C 14/18

(52) U.S. Cl. CPC C03C 17/3607; C03C 2218/155; C03C 17/3634; C03C 17/3642; C03C 17/3649; C03C 17/3657; C23C 14/352; C23C 14/0036; C23C 14/0635; C23C 14/085; C23C 14/0617; C23C 14/067; C23C 14/083; C23C 14/185; C03C 2218/156; C03C 17/3626

(57) ABSTRACT

The present disclosure provides a colored glass and a preparation method thereof. The colored glass comprises a glass substrate, layer Aed structure and a Ti alloy layer, wherein the layered structure and the Ti alloy layer are laminated on the surface of the glass substrate; the layered structure comprises alternately stacked layer A and layer B; the layer A is a SiC or NiO layer; the layer B is an MN layer, a GaN layer, a ZrO₂ layer or an Nb₂O₅ layer; the layer A is in contact with the glass substrate, the layer B is in contact with the Ti alloy layer. The color of the glass is controlled by adjusting the thickness of the layer A and the layer B in the layered structure. The Ti alloy layer has high reflectivity, which can make the colored glass bright in color, and has a certain protective and corrosion-resistant effect.

### CROSS-REFERENCE TO RELATED APPLICATIONS

This application claims priority to Chinese Application Serial No. 202010200630.9, filed Mar. 20, 2020, the content of which is incorporated herein by reference in its entirety.

### TECHNICAL FIELD

The present disclosure pertains to the film-coating technical field, and in particular to a colored glass and a preparation method thereof.

### BACKGROUND

Glass is the most common material in daily life and is closely related to production activities. With the development of modern scientific technology and glass technology as well as the improvement of living standards, the function of architectural glass is not only to meet the lighting requirements, but to have characteristics of light adjustment, heat preservation and insulation, being bulletproof, theft-resistance, being fireproof, radiation-resistance and electromagnetic interference-resistance, artistic decoration, etc.

Traditional colored glass is generally prepared by online preparation process. For example, with methods of chemical preparation and spray printing, a product produced by such methods has a single color, and one color corresponds to one process. If the color of the product needs to be changed, the preparation conditions have to be changed. The process is extremely complicated, and the costs of changing color are high. For example, it is necessary to replace the glass melt components of the entire melting pool and clean the melting pool sufficiently and thoroughly (the volume of the melting pool is comparatively large); or change the organic coating materials sprayed or printed on the glass surface. The above methods are time-consuming, costly, and do not meet the requirements for the preparation of modern new products. Moreover, the products prepared by such methods generate a large amount of waste, some of which are toxic and unfriendly to the environment. In addition, for these preparation methods which utilize the color of the material per se, the product performance is greatly affected by the uniformity of the material, and the color of the product is not stable.

### SUMMARY

It is an object of the present disclosure to provide a colored glass and a preparation method thereof. The colored glass of the present disclosure is prepared by off-line process using the film-interference principle. The product color system is rich; changing color is easy; and the color is stable.

In order to achieve the above inventive object, the present disclosure provides the following technical solutions:

The present disclosure provides a colored glass comprising a glass substrate, a layered structure laminated on the surface of the glass substrate and a Ti alloy layer; the layered structure comprises alternately stacked layer A and layer B; the layer A is a SiC or NiO layer; the layer B is an AlN, GaN, ZrO₂ or Nb₂O₅ layer; the layer A is in contact with the glass substrate, and the layer B is in contact with the Ti alloy layer.

Preferably, the total number of layers of the layer A and the layer B is at least 2.

Preferably, the total number of layers of the layer A and the layer B is 2 to 100.

Preferably, the single layer thickness of the layer A is independently 20 to 150 nm.

Preferably, the single layer thickness of the layer B is independently 30 to 200 nm.

Preferably, the titanium alloy layer is made of a titanium-aluminum alloy or a titanium-chromium alloy, and the thickness of the Ti alloy layer is 30 to 300 nm.

The present disclosure also provides a method for preparing the colored glass as described in the above solutions, comprising the following steps: corresponding to the structure of the colored glass, coating the layer A and the layer B alternately on the surface of the glass substrate by magnetron sputtering, and finally coating the Ti alloy layer on the surface of the layer B to obtain the colored glass;

The layer A is in contact with the glass substrate; the layer A is a SiC or NiO layer; the layer B is an AlN, GaN, ZrO₂ or Nb₂O₅ layer.

Preferably, when the layer A is a SiC layer, the layer A is coated by magnetron sputtering under the following conditions: the power of magnetron sputtering is 50 to 150 W; the sputtering target is a high-purity SiC target; the sputtering gas pressure is 0.2 to 0.9 Pa; the argon flow rate is 40 to 100 sccm;

When the layer A is a NiO layer, the layer A is coated by magnetron sputtering under the following conditions: the power of magnetron sputtering is 10 to 200 W; the sputtering target is a high-purity Ni target; the sputtering gas pressure is 0.1 to 1 Pa; the argon flow rate is 40 to 100 sccm; the oxygen flow rate is 4 to 25 sccm; the flow ratio of argon to oxygen is (4 to 10):1.

Preferably, when the layer B is an AlN layer, the layer B is coated by magnetron sputtering under the following conditions: the power of magnetron sputtering is 10 to 200 W; the sputtering target is a high-purity Al target; the sputtering gas pressure is 0.1 to 1 Pa; the argon flow rate is 40 to 100 sccm; the nitrogen flow rate is 8 to 50 sccm, the flow ratio of argon to nitrogen during sputtering is (2 to 8):1;

When the layer B is a GaB layer, the layer B is coated by magnetron sputtering under the following conditions: the sputtering power is 10 to 200 W; the sputtering target is a high-purity Ga target; the sputtering gas pressure is 0.1 to 1 Pa; the argon flow rate is 40 to 100 sccm; the nitrogen flow rate is 8 to 50 sccm, the flow ratio of argon to nitrogen during sputtering is (2 to 8):1;

When the layer B is a ZrO₂ layer, the layer B is coated by magnetron sputtering under the following conditions: the sputtering power is 10 to 200 W; the sputtering target is a high-purity ZrO₂ target; the sputtering gas pressure is 0.1 to 1 Pa; the argon flow rate is 40 to 100 sccm; the oxygen flow rate is 4 to 25 sccm, the flow ratio of argon to oxygen is (4 to 10):1;

When the layer B is a Nb₂O₅ layer, the layer B is coated by magnetron sputtering under the following conditions: the sputtering power is 10 to 200 W; the sputtering target is a high-purity Nb target; the sputtering gas pressure is 0.1 to 1 Pa; the argon flow rate is 40 to 100 sccm; the nitrogen flow rate is 4 to 25 sccm, the flow ratio of argon to nitrogen during sputtering is (4 to 10):1.

Preferably, the Ti alloy layer is coated by magnetron sputtering under the following conditions: the sputtering power is 10 to 150 W; the sputtering target is a Ti/Al alloy target or a Ti/Cr alloy target; the sputtering gas pressure is 0.1 to 1 Pa; the argon flow rate is 40 to 100 sccm.

The present disclosure provides a colored glass comprising a glass substrate, a layered structure laminated on the surface of the glass substrate and a Ti alloy layer; the layered structure comprises alternately stacked layer A and layer B; the layer A is a SiC or NiO layer; the layer B is an AlN, GaN, ZrO₂ or Nb₂O₅ layer; the layer A is in contact with the glass substrate, and the layer B is in contact with the Ti alloy layer. The present disclosure uses the different materials of the layer A and the layer B and the refractive index difference between the layers to make the glass exhibit color. The color of the glass is controlled by adjusting the thickness of the layer A and the layer B in the layered structure. The Ti alloy layer has high reflectivity, which can make the colored glass bright in color, and has a certain protective and corrosion-resistant effect. The results of the examples show that the colored glass of the present disclosure has a bright color and a rich color system; the surface color does not change after tempering treatment; and the product color is stable.

In addition, the material of each layer of the colored glass of the present disclosure has good chemical stability, so the obtained colored glass is resistant to acid and alkali corrosion, and the glass surface material is non-toxic and friendly to the environment.

The present disclosure provides a method for preparing the colored glass as described in the above solutions. By using the magnetron sputtering method, products of varying colors can be obtained by adjusting the process parameters without changing the target material. Compared with the existing preparation processes, the present disclosure has a simple process, a high fault tolerance rate and easy to change color, which does not need to change the preparation conditions. Changing color can be achieved only by adjusting the preparation process parameters of each film layer on the glass surface in the equipment and adjusting the thickness of each film layer. The cost is significantly reduced; the color system is rich and the product color is stable and resistant to acid and alkali corrosion.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is an effect picture of the product of Example 1.

FIG. 2 is an effect picture of the product of Example 2.

FIG. 3 is an effect picture of the product of Example 3.

FIG. 4 is an effect picture of the product of Example 4.

FIG. 5 is an effect picture of the product of Example 5.

FIG. 6 is a diagram showing transmittance and reflectivity changes of the product of Example 3 before and after annealing.

### DETAILED DESCRIPTION

The present disclosure provides a colored glass, comprising a glass substrate, a layered structure laminated on the surface of the glass substrate and a Ti alloy layer; the layered structure comprises alternately stacked layer A and layer B; the layer A is a SiC or NiO layer; the layer B is an AlN, GaN, ZrO₂ or Nb₂O₅ layer; the layer A is in contact with the glass substrate, and the layer B is in contact with the Ti alloy layer.

The colored glass provided by the present disclosure comprises a glass substrate. The glass substrate is not particularly limited, as long as the glass substrate is well known in the art. In the examples of the present disclosure, the glass substrate is a transparent glass.

The colored glass provided by the present disclosure comprises a layered structure laminated on the surface of the glass substrate; the layered structure comprises alternately stacked layer A and layer B; the layer A is a SiC or NiO layer; the layer B is an AlN, GaN, ZrO₂ or Nb₂O₅ layer; the layer A is in contact with the glass substrate.

In the present disclosure, the total number of layers of the layer A and the layer B is at least 2, preferably 2 to 100, more preferably 2 to 50, which can be selected by a person skilled in the art according to actual needs.

In the present disclosure, the layers A in the colored glass may be all SiC layers or NiO layers, or some layers are SiC layers, while the remaining layers are NiO layers. Likewise, the layers B in the colored glass of the present disclosure may be all AlN layers, or GaN layers, or ZrO₂ layers, or Nb₂O₅ layers, or a combination of the above layers.

In the present disclosure, the thickness of the single layer of the layer A is independently preferably 20 to 150 nm, and in the examples of the present disclosure, it is specifically 50, 70, 90, 110 or 120 nm; the thickness of the single layer of the layer B is independently preferably 30 to 200 nm, more preferably 30 to 150 nm, and in the examples of the present disclosure, it is specifically 40, 55 or 80 nm. In the present disclosure, the thickness of each layer is different, and the color of the corresponding colored glass is different. The color of each layer can be configured by a person skilled in the art according to actual needs.

The colored glass provided by the present disclosure comprises a Ti alloy layer; the Ti alloy layer is in contact with the layer B. In the present disclosure, the thickness of the Ti alloy layer is preferably 30 to 300 nm, more preferably 30 to 150 nm. In the examples of the present disclosure, it is specifically 30, 50 or 80 nm. In the present disclosure, the Ti alloy layer is preferably made of a titanium-aluminum alloy or a titanium-chromium alloy, more preferably a titanium-aluminum alloy. The molar ratio of titanium atoms to aluminum atoms in the titanium-aluminum alloy is preferably 1:1, and the molar ratio of titanium atoms to chromium atoms in the titanium-chromium alloy is preferably 1:1. The Ti alloy layer of the present disclosure has a high reflectivity (the reflectivity at 650 nm is higher than 90%), which can make the colored glass bright in color and has a certain protective and corrosion-resistant effect.

In the colored glass of the present disclosure, the materials of the layer A and the layer B are different. There is a refractive index difference between the layers to make the glass exhibit color. The color of the glass can be further controlled by adjusting the thickness of each layer in the layered structure. The obtained colored glass has a bright color and a rich color system, and the color is stable.

The present disclosure provides a method for preparing the colored glass as described in the above solutions, comprising the following steps: corresponding to the structure of the colored glass, coating the layer A and the layer B alternately on the surface of the glass substrate by magnetron sputtering, and finally coating the Ti alloy layer on the surface of the layer B to obtain the colored glass.

The layer A is in contact with the glass substrate; the layer A is a SiC or NiO layer; the layer B is an AlN, GaN, ZrO₂ or Nb₂O₅ layer.

In the present disclosure, a layer A is first coated on the surface of the glass substrate by magnetron sputtering to form the first layer A.

In the present disclosure, the magnetron sputtering apparatus is not particularly limited, as long as the magnetron sputtering apparatus is well known in the art. In the examples of the present disclosure, the model of the magnetron sputtering apparatus is TSU-650; the power source used for the magnetron sputtering apparatus is preferably a radio frequency power source.

In the present disclosure, when the layer A is a SiC layer, the layer A is coated by magnetron sputtering under the following preferred conditions: the power of the magnetron sputtering is 50 to 150 W; the sputtering target is a high-purity SiC target; the sputtering gas pressure is 0.2 to 0.9 Pa; and the argon flow rate is 40 to 100 sccm; the power of the magnetron sputtering is further preferably 50 to 100 W, more preferably 60 to 100 W; the sputtering gas pressure is further preferably 0.3 to 0.8 Pa; the argon flow rate is further preferably 40 to 80 sccm.

In the present disclosure, when the layer A is a NiO layer, the layer A is coated by magnetron sputtering under the following preferred conditions: the power of the magnetron sputtering is 10 to 200 W; the sputtering target is a high-purity Ni target; and the sputtering gas pressure is 0.1 to 1 Pa; the argon flow rate is 40 to 100 sccm; the oxygen flow rate is 4 to 25 sccm; and the flow ratio of argon to oxygen is (4 to 10):1; the power of the magnetron sputtering is further preferably 50 to 120 W, more preferably 60 to 100 W; the sputtering gas pressure is further preferably 0.2 to 0.9 Pa, more preferably 0.3 to 0.8 Pa; the oxygen flow rate is further preferably 5 to 25 sccm, more preferably 7 to 25 sccm; the flow rate ratio of argon to oxygen is further preferably (4 to 8):1, more preferably (4 to 6):1.

In the present disclosure, the thickness of the deposited first layer A corresponds to the thickness of the first layer A in the colored glass.

After forming the first layer A, in the present disclosure, a layer B is coated on the surface of the first layer A by magnetron sputtering to form the first layer B.

In the present disclosure, when the layer B is an MN layer, the layer B is coated by magnetron sputtering under the following preferred conditions: the power of magnetron sputtering is 10 to 200 W; the sputtering target is a high-purity Al target; the sputtering gas pressure is 0.1 to 1 Pa; the argon flow rate is 40 to 100 sccm; the nitrogen flow rate is 8 to 50 sccm; the flow ratio of argon to nitrogen during sputtering is (2 to 8):1; the power of the magnetron sputtering is further preferably 50 to 150 W, more preferably 60 to 120 W; the sputtering gas pressure is further preferably 0.2 to 0.9 Pa, more preferably 0.3 to 0.8 Pa; the nitrogen flow rate is further preferably 8 to 40 sccm, more preferably 8 to 30 sccm; the flow ratio of argon to nitrogen during sputtering is further preferably (3 to 7):1, more preferably (4 to 6):1.

In the present disclosure, when the layer B is an GaN layer, the layer B is coated by magnetron sputtering under the following preferred conditions: the sputtering power is 10 to 200 W; the sputtering target is a high-purity Ga target; and the sputtering gas pressure is 0.1 to 1 Pa; the argon flow rate is 40 to 100 sccm; the nitrogen flow rate is 8 to 50 sccm; the flow ratio of argon to nitrogen during sputtering is (2 to 8):1; the sputtering power is further preferably 50 to 150 W, more preferably 60 to 100 W; the sputtering gas pressure is further preferably 0.2 to 0.9 Pa, more preferably 0.3 to 0.8 Pa; the nitrogen flow rate is further preferably 8 to 40 sccm, more preferably 8 to 25 sccm; the flow ratio of argon to nitrogen during sputtering is further preferably (3 to 8):1, and more preferably (5 to 8):1.

In the present disclosure, when the layer B is a ZrO₂ layer, the layer B is coated by magnetron sputtering under the following preferred conditions: the sputtering power is 10 to 200 W; the sputtering target is a high-purity ZrO₂ target; the sputtering gas pressure is 0.1 to 1 Pa; the argon flow rate is 40 to 100 sccm; the oxygen flow rate is 4 to 25 sccm; the flow ratio of argon to oxygen is (4 to 10):1; the sputtering power is further preferably 50 to 150 W, more preferably 60 to 120 W; the sputtering gas pressure is further preferably 0.2 to 0.9 Pa, more preferably 0.3 to 0.8 Pa; the oxygen flow rate is further preferably 4 to 20 sccm, more preferably 4 to 15 sccm; the flow ratio of argon to oxygen is further preferably (5 to 9):1, more preferably (5 to 7):1.

In the present disclosure, when the layer B is a Nb₂O₅ layer, the layer B is coated by magnetron sputtering under the following preferred conditions: the sputtering power is 10 to 200 W; the sputtering target is a high-purity Nb target; the sputtering gas pressure is 0.1 to 1 Pa; the argon flow rate is 40 to 100 sccm; the oxygen flow rate is 4 to 25 sccm; the flow ratio of argon to oxygen is (4 to 10):1; the sputtering power is further preferably 50 to 150 W, more preferably 60 to 120 W; the sputtering gas pressure is further preferably 0.2 to 0.9 Pa, more preferably 0.3 to 0.8 Pa; the oxygen flow rate is further preferably 4 to 20 sccm, more preferably 4 to 15 sccm; the flow ratio of argon to oxygen is further preferably (5 to 9):1, more preferably (6 to 9):1.

In the present disclosure, the thickness of the deposited first layer B corresponds to the thickness of the first layer B in the colored glass.

After forming the first layer B, in the present disclosure, a layer A is continually coated on the surface of the first layer B by magnetron sputtering to form the second layer A; then a layer B is continually coated on the surface of the second layer A to form the second layer B; the coating is performed alternately in this manner until the desired layered structure is obtained with the last layer of the layer structure being the layer B.

In the present disclosure, the layer A is coated each time under conditions the same as the conditions under which the first layer A is prepared, and the layer B is coated each time under conditions the same as the conditions under which the first layer B is prepared, which will not be repeated herein. Since the chamber volume and target area of different magnetron sputtering coating apparatuses are different, a person skilled in the art can select suitable coating conditions within the above ranges according to different magnetron sputtering coating apparatuses.

After obtaining the layered structure, in the present disclosure, a Ti alloy layer is coated by magnetron sputtering on the surface of the layered structure.

The Ti alloy layer is coated by magnetron sputtering in the present disclosure under the following preferred conditions: the sputtering power is 10 to 150 W; the sputtering target is a Ti/Al alloy target or a Ti/Cr alloy target; the sputtering gas pressure is 0.1-1 Pa; the argon flow rate is 40 to 100 sccm. The sputtering power is further preferably 50 to 120 W, more preferably 60 to 100 W; the sputtering gas pressure is further preferably 0.2 to 0.9 Pa, more preferably 0.3 to 0.8 Pa; the argon flow rate is further preferably 40 to 80 sccm, more preferably 40 to 65 sccm; the atomic molar ratio of Ti/Al in the Ti/Al alloy target is preferably 1:1, and the atomic molar ratio of Ti/Cr in the Ti/Cr alloy target is preferably 1:1.

The preparation of a colored glass by use of the method of the present disclosure allows for the obtaining of different thicknesses by adjusting the process parameters without changing the target material, thereby allowing for the obtaining of products of varying colors. The process is simple; the fault tolerance rate is high; changing color is easy; the color system is rich; the product color is stable and is resistant to acid and alkali corrosion.

The colored glass provided by the present disclosure and the preparation method thereof are described in detail below in conjunction with examples, but they cannot be understood as limiting the protection scope of the present disclosure.

The model of the magnetron sputtering coating apparatus used in the following examples is TSU-650.

### Example 1

The layered structure of the colored glass is a double-layer structure. In the preparation of the first layer, the used sputtering target is a high-purity SiC target; the power of magnetron sputtering is 90 W; the sputtering gas pressure is 0.7 Pa; the argon flow rate is 40 sccm; the main component is SiC; the thickness of the film layer is 50 nm.

In the preparation of the second layer, the used sputtering target is a high-purity Al target; the power of magnetron sputtering is 90 W; the sputtering gas pressure is 0.7 Pa; the argon flow rate is 40 sccm; the main component is AlN; the flow ratio of argon to nitrogen during sputtering is 4:1; the thickness of the film layer is 40 nm.

In the preparation of the Ti alloy layer, the used sputtering target is a Ti/Al alloy target (atomic ratio of 1:1); the power of magnetron sputtering is 60 W; the sputtering gas pressure is 0.7 Pa; the argon flow rate is 50 sccm; the thickness of the film layer is 30 nm.

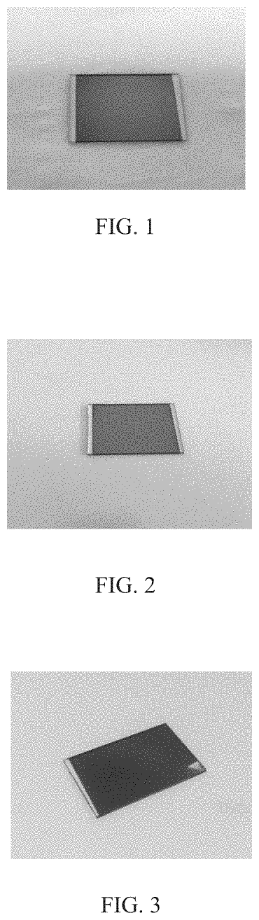

The prepared colored glass is blue, and the specific product is as shown in FIG. 1.

### Example 2

The layered structure of the colored glass is a four-layer structure. In the preparation of the first layer, the used sputtering target is a high-purity SiC target; the power of magnetron sputtering is 90 W; the sputtering gas pressure is 0.7 Pa; the argon flow rate is 40 sccm; the main component is SiC; the thickness of the film layer is 90 nm.

In the preparation of the second layer, the used sputtering target is a high-purity Ga target; the power of magnetron sputtering is 90 W; the sputtering gas pressure is 0.7 Pa; the argon flow rate is 40 sccm; the main component is GaN; the flow ratio of argon to nitrogen during sputtering is 8:1; the thickness of the film layer is 40 nm.

In the preparation of the third layer, the used sputtering target is a high-purity SiC target; the power of magnetron sputtering is 90 W; the sputtering gas pressure is 0.7 Pa; the argon flow rate is 40 sccm; the main component is SiC; the thickness of the film layer is 90 nm.

In the preparation of the fourth layer, the used sputtering target is a high-purity Ga target; the power of magnetron sputtering is 90 W; the sputtering gas pressure is 0.7 Pa; the argon flow rate is 40 sccm; the main component is GaN; the flow ratio of argon to nitrogen during sputtering is 8:1; the thickness of the film layer is 40 nm.

In the preparation of the Ti alloy layer, the used sputtering target is a Ti/Al alloy target (atomic ratio of 1:1); the power of magnetron sputtering is 90 W; the sputtering gas pressure is 0.5 Pa; the argon flow rate is 55 sccm; the thickness of the film layer is 50 nm.

The prepared colored glass is green, and the specific product is as shown in FIG. 2.

### Example 3

The layered structure of the colored glass is a double-layer structure. In the preparation of the first layer, the used sputtering target is a high-purity Ni target; the power of magnetron sputtering is 90 W; the sputtering gas pressure is 0.4 Pa; the argon flow rate is 40 sccm; the main component is NiO; the flow ratio of argon to oxygen during sputtering is 5:1; the thickness of the film layer is 70 nm.

In the preparation of the second layer, the used sputtering target is a high-purity Ga target; the power of magnetron sputtering is 90 W; the sputtering gas pressure is 0.7 Pa; the argon flow rate is 40 sccm; the main component is GaN; the flow ratio of argon to nitrogen during sputtering is 8:1; the thickness of the film layer is 40 nm.

In the preparation of the Ti alloy layer, the used sputtering target is a Ti/Cr alloy target (atomic ratio of 1:1); the power of magnetron sputtering is 90 W; the sputtering gas pressure is 0.8 Pa; the argon flow rate is 40 sccm; the thickness of the film layer is 80 nm.

The prepared colored glass is purple-red, and the specific product is as shown in FIG. 3.

### Example 4

The layered structure of the colored glass is a double-layer structure. In the preparation of the first layer, the used sputtering target is a high-purity Ni target; the power of magnetron sputtering is 90 W; the sputtering gas pressure is 0.4 Pa; the argon flow rate is 40 sccm; the main component is NiO; the flow ratio of argon to oxygen during sputtering is 5:1; the thickness of the film layer is 110 nm.

In the preparation of the second layer, the used sputtering target is a high-purity ZrO₂ target; the power of magnetron sputtering is 90 W; the sputtering gas pressure is 0.7 Pa; the argon flow rate is 40 sccm; the main component is ZrO₂; the flow ratio of argon to oxygen during sputtering is 6:1; the thickness of the film layer is 80 nm.

In the preparation of the Ti alloy layer, the used sputtering target is a Ti/Cr alloy target (atomic ratio of 1:1); the power of magnetron sputtering is 90 W; the sputtering gas pressure is 0.5 Pa; the argon flow rate is 55 sccm; the thickness of the film layer is 50 nm.

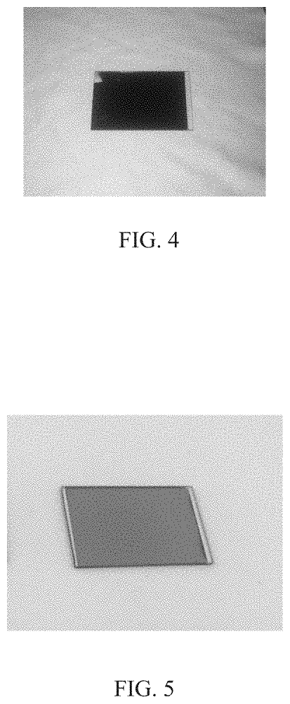

The prepared colored glass is black, and the specific product is as shown in FIG. 4.

### Example 5

The layered structure of the colored glass is a double-layer structure. In the preparation of the first layer, the used sputtering target is a high-purity SiC target; the power of magnetron sputtering is 90 W; the sputtering gas pressure is 0.7 Pa; the argon flow rate is 40 sccm; the main component is SiC; the thickness of the film layer is 120 nm.

In the preparation of the second layer, the used sputtering target is a high-purity Nb target; the power of magnetron sputtering is 90 W; the sputtering gas pressure is 0.8 Pa; the argon flow rate is 40 sccm; the main component is Nb₂O₅; the flow ratio of argon to oxygen during sputtering is 9:1; the thickness of the film layer is 55 nm.

In the preparation of the Ti alloy layer, the used sputtering target is a Ti/Al alloy target (atomic ratio of 1:1); the power of magnetron sputtering is 90 W; the sputtering gas pressure is 0.5 Pa; the argon flow rate is 50 sccm; the thickness of the film layer is 50 nm.

The prepared colored glass is gold, and the specific product is as shown in FIG. 5.

Performance Test

(1) The color glasses of Examples 1 to 5 are tested for acid resistance. The test method is carried out according to the Chinese national standard GB6459-86 acetic acid salt spray test. The testing time is 48 hours. During the test, the film surfaces of Examples 1 to 5 show no corrosion and discoloration, indicating that the films prepared by the present disclosure can have good resistance to acid salts.

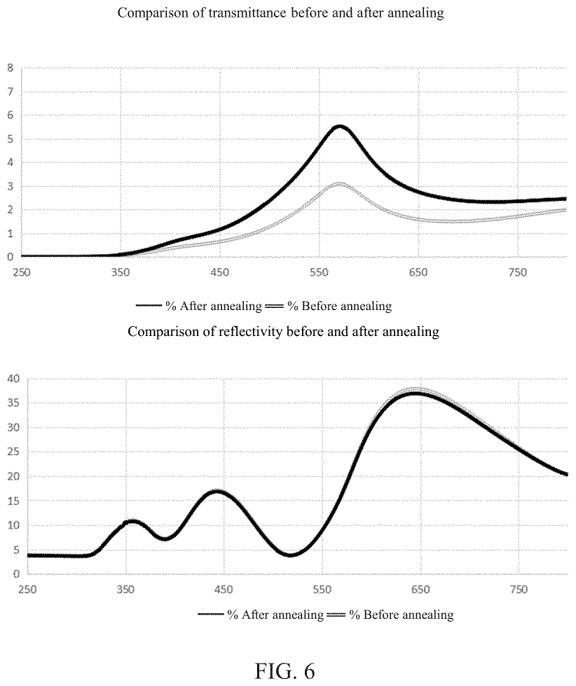

(2) The colored glass of Example 3 is subjected to a rapid annealing treatment to test the high temperature resistance thereof and whether it allows tempering. The rapid annealing temperature is 500° C.; the time is 30 minutes; the annealing atmosphere is atmospheric atmosphere; the annealing pressure is atmospheric pressure. The samples before and after the test are measured for the transmittance and reflectivity of the visible light waveband. As shown in FIG. 6, the ordinate represents the percentage of light intensity, and the abscissa represents the wavelength of light in nanometers. FIG. 6 shows that there is no change in the position of the peak before and after the annealing treatment, indicating that the color of the colored glass does not change; moreover, the glass transmittance after rapid annealing is slightly increased but does not change much (increased by about 2%), and there is no change in the reflectivity, indicating that the product has a stable color and a good heat resistance.

The colored glasses of Examples 1 to 2 and 4 to 5 are subjected to the rapid annealing treatment. The results are similar to those of Example 3, showing that the position of the peak does not shift. The glass transmittance is slightly increased but does not change much, and there is no change in the reflectivity, indicating that the product has a good heat resistance and a stable color.

It can be seen from the above examples that the present disclosure provides a colored glass and a preparation method thereof. The colored glass of the present disclosure utilizes the film-interference principle, has a rich color system and a stable color. The method of the present disclosure allows for the obtaining of products of varying colors by adjusting the process parameters without changing the target material. The process is simple; the fault tolerance rate is high; and changing color is easy.

The above examples are only the preferred examples of the present disclosure. It should be pointed out that a person of ordinary skill in the art, without departing from the principle of the present disclosure, may make improvements and modifications, and these improvements and modifications should also be regarded as within the protection scope of the present disclosure.

What is claimed is:

1. A colored glass comprising:
a glass substrate,
a layered structure laminated on the surface of the glass substrate;
and a Ti alloy layer;
wherein the layered structure comprises alternately stacked layer A and layer B; wherein the layer A is a SiC or NiO layer and the layer B is an AlN, GaN, ZrO₂ or Nb₂O₅ layer; wherein the layer A is in contact with the glass substrate and the layer B is in contact with the Ti alloy layer.

2. The colored glass according to claim 1, wherein a total number of layers of the layer A and the layer B is at least 2.

3. The colored glass according to claim 2, wherein a total number of layers of the layer A and the layer B is 2 to 100.

4. The colored glass according to claim 1, wherein a single layer thickness of the layer A is independently 20 to 150 nm.

5. The colored glass according to claim 2, wherein a single layer thickness of the layer A is independently 20 to 150 nm.

6. The colored glass according to claim 3, wherein a single layer thickness of the layer A is independently 20 to 150 nm.

7. The colored glass according to claim 1, wherein a single layer thickness of the layer B is independently 30 to 200 nm.

8. The colored glass according to claim 2, wherein a single layer thickness of the layer B is independently 30 to 200 nm.

9. The colored glass according to claim 3, wherein a single layer thickness of the layer B is independently 30 to 200 nm.

10. The colored glass according to claim 1, wherein the titanium alloy layer is made of a titanium-aluminum alloy or a titanium-chromium alloy, and a thickness of the Ti alloy layer is 30 to 300 nm.

11. The colored glass according to claim 2, wherein the titanium alloy layer is made of a titanium-aluminum alloy or a titanium-chromium alloy, and a thickness of the Ti alloy layer is 30 to 300 nm.

12. The colored glass according to claim 3, wherein the titanium alloy layer is made of a titanium-aluminum alloy or a titanium-chromium alloy, and a thickness of the Ti alloy layer is 30 to 300 nm.

13. A method for preparing the colored glass according to claim 1, comprising the following steps:
corresponding to a structure of the colored glass, coating the layer A and the layer B alternately on the surface of the glass substrate by magnetron sputtering, and
coating the Ti alloy layer on the surface of the layer B to obtain the colored glass;
wherein the layer A is in contact with the glass substrate; wherein the layer A is a SiC or NiO layer; wherein the layer B is an AlN, GaN, ZrO₂ or Nb₂O₅ layer.

14. A method for preparing the colored glass according to claim 2, comprising the following steps:
corresponding to a structure of the colored glass, coating the layer A and the layer B alternately on the surface of the glass substrate by magnetron sputtering, and
coating the Ti alloy layer on the surface of the layer B to obtain the colored glass;
wherein the layer A is in contact with the glass substrate; wherein the layer A is a SiC or NiO layer; wherein the layer B is an AlN, GaN, ZrO₂ or Nb₂O₅ layer.

15. A method for preparing the colored glass according to claim 3, comprising the following steps:
corresponding to a structure of the colored glass, coating the layer A and the layer B alternately on the surface of the glass substrate by magnetron sputtering, and
coating the Ti alloy layer on the surface of the layer B to obtain the colored glass;
wherein the layer A is in contact with the glass substrate; wherein the layer A is a SiC or NiO layer; wherein the layer B is an AlN, GaN, ZrO₂ or Nb₂O₅ layer.

16. A method for preparing the colored glass according to claim 4, comprising the following steps:
corresponding to a structure of the colored glass, coating the layer A and the layer B alternately on the surface of the glass substrate by magnetron sputtering, and
coating the Ti alloy layer on the surface of the layer B to obtain the colored glass;
wherein the layer A is in contact with the glass substrate; wherein the layer A is a SiC or NiO layer; wherein the layer B is an AlN, GaN, ZrO₂ or Nb₂O₅ layer.

17. A method for preparing the colored glass according to claim 7, comprising the following steps:
corresponding to a structure of the colored glass, coating the layer A and the layer B alternately on the surface of the glass substrate by magnetron sputtering, and
coating the Ti alloy layer on the surface of the layer B to obtain the colored glass;
wherein the layer A is in contact with the glass substrate; wherein the layer A is a SiC or NiO layer; wherein the layer B is an AlN, GaN, ZrO₂ or Nb₂O₅ layer.

18. The preparation method according to claim 13, wherein:
when the layer A is a SiC layer, the layer A is coated by magnetron sputtering under conditions comprising:
a power of magnetron sputtering is 50 to 150 W;
a sputtering target is a high-purity SiC target;
a sputtering gas pressure is 0.2 to 0.9 Pa; and
an argon flow rate is 40 to 100 sccm; or
when the layer A is a NiO layer, the layer A is coated by magnetron sputtering under conditions comprising:
the power of magnetron sputtering is 10 to 200 W;
the sputtering target is a high-purity Ni target;
the sputtering gas pressure is 0.1 to 1 Pa;
the argon flow rate is 40 to 100 sccm;
an oxygen flow rate is 4 to 25 sccm; and
a flow ratio of argon to oxygen is (4 to 10):1.

19. The preparation method according to claim 13, wherein:
when the layer B is an MN layer, the layer B is coated by magnetron sputtering under conditions comprising:
a power of magnetron sputtering is 10 to 200 W;
a sputtering target is a high-purity Al target;
a sputtering gas pressure is 0.1 to 1 Pa;
an argon flow rate is 40 to 100 sccm;
a nitrogen flow rate is 8 to 50 sccm; and
a flow ratio of argon to nitrogen during sputtering is (2 to 8):1; or
when the layer B is a GaB layer, the layer B is coated by magnetron sputtering under conditions comprising:
the sputtering power is 10 to 200 W;
the sputtering target is a high-purity Ga target;
the sputtering gas pressure is 0.1 to 1 Pa;
the argon flow rate is 40 to 100 sccm;
the nitrogen flow rate is 8 to 50 sccm; and
the flow ratio of argon to nitrogen during sputtering is (2 to 8):1; or
when the layer B is a ZrO₂ layer, the layer B is coated by magnetron sputtering under conditions comprising:
the sputtering power is 10 to 200 W;
the sputtering target is a high-purity ZrO₂ target;
the sputtering gas pressure is 0.1 to 1 Pa;
the argon flow rate is 40 to 100 sccm;
the oxygen flow rate is 4 to 25 sccm; and
the flow ratio of argon to oxygen is (4 to 10):1; or
when the layer B is a Nb₂O₅ layer, the layer B is coated by magnetron sputtering under conditions comprising:
the sputtering power is 10 to 200 W;
the sputtering target is a high-purity Nb target;
the sputtering gas pressure is 0.1 to 1 Pa;
the argon flow rate is 40 to 100 sccm;
the nitrogen flow rate is 4 to 25 sccm; and
the flow ratio of argon to nitrogen during sputtering is (4 to 10):1.

20. The preparation method according to claim 13, wherein the Ti alloy layer is coated by magnetron sputtering under conditions comprising:
a sputtering power is 10 to 150 W;
a sputtering target is a Ti/Al alloy target or a Ti/Cr alloy target;
a sputtering gas pressure is 0.1 to 1 Pa; and
an argon flow rate is 40 to 100 sccm.
